(19) United States
(12) Patent Application Publication
(10) Pub. No.: US 2026/0135554 A1
(43) Pub. Date: May 14, 2026

(54) SIGNAL PROCESSING CIRCUIT AND SEMICONDUCTOR DEVICE

(71) Applicant: FUJI ELECTRIC CO., LTD., Kawasaki-shi (JP)

(72) Inventor: Takato SUGAWARA, Matsumoto-city (JP)

(73) Assignee: FUJI ELECTRIC CO., LTD., Kawasaki-shi (JP)

(21) Appl. No.: 19/342,285

(22) Filed: Sep. 26, 2025

(30) Foreign Application Priority Data
Nov. 13, 2024 (JP) 2024-198414

(51) Int. Cl. H03K 17/567

(52) U.S. Cl. CPC H03K 17/567

(57) ABSTRACT

A signal processing circuit, including: a power supply line configured to receive a first power supply voltage; a signal line configured to receive an input signal; a power supply circuit configured to receive the first power supply voltage from the power supply line; a capacitor connected to the power supply circuit, the power supply circuit generating a second power supply voltage at the capacitor based on the received first power supply voltage; a discharge circuit configured to discharge the capacitor, in response to the first power supply voltage dropping below a predetermined voltage level; a first detection circuit configured to operate based on the second power supply voltage, and detect a falling edge of the input signal inputted through the signal line; and a first diode having an anode thereof connected to the signal line and a cathode thereof connected to the power supply line.

### CROSS-REFERENCE TO RELATED APPLICATIONS

The present application claims priority pursuant to 35 U.S.C. § 119 from Japanese patent application number 2024-198414 filed on Nov. 13, 2024, the entire disclosure of which is hereby incorporated by reference herein.

### BACKGROUND

### Technical Field

The present disclosure relates to a signal processing circuit and a semiconductor device.

### Description of the Related Art

For example, integrated circuits may include a power supply circuit that generates an internal power supply voltage from an external power supply voltage of such an integrated circuit, and a signal processing circuit that operates based on the internal power supply voltage (for example, Japanese patent application publication Nos. 2021-083072 and 2007-305010).

Typical power supply circuits include a capacitor in which an internal power supply voltage is generated. Thus, even if an external power supply voltage drops instantaneously, the internal power supply voltage may not drop. In such a situation, a signal processing circuit would sometimes malfunction when processing signals that are based on the external power supply voltage.

### SUMMARY

An aspect of the present disclosure is a signal processing circuit comprising: a power supply circuit configured to generate, based on a first power supply voltage applied to a power supply line, a second power supply voltage at a capacitor; a discharge circuit configured to discharge the capacitor, in response to the first power supply voltage dropping below a predetermined voltage level; a first detection circuit configured to operate based on the second power supply voltage, and detect a falling edge of an input signal inputted through a signal line; and a first diode having an anode connected to the signal line and a cathode connected to the power supply line.

Another aspect of the present disclosure is a semiconductor device comprising: a first switching device on a power supply side, a second switching device on a ground side, and a switching control circuit configured to control switching of the first switching device and the second switching device, the first switching device and the second switching device being configured to drive a load, the switching control circuit including a power supply circuit configured to generate, based on a first power supply voltage applied to a power supply line, a second power supply voltage at a capacitor, a discharge circuit configured to discharge the capacitor, in response to the first power supply voltage dropping below a predetermined voltage level, a first detection circuit configured to operate based on the second power supply voltage, and detect a falling edge of an input signal inputted through a signal line, a second detection circuit configured to operate based on the second power supply voltage, and detect a rising edge of the input signal inputted through the signal line, a first driver circuit configured to drive the first switching device, in response to a first detection result of the first detection circuit and a second detection result of the second detection circuit, a second driver circuit configured to drive the second switching device in response to the input signal, and a first diode having an anode connected to the signal line and a cathode connected to the power supply line.

### BRIEF DESCRIPTION OF THE DRAWINGS

FIG. 1 is a diagram illustrating an example of a power module 10.

FIG. 2 is a diagram illustrating an example of a configuration of a power supply circuit 40.

FIG. 3 is a diagram illustrating an example of a configuration of a pulse generation circuit 48.

FIG. 4 is a diagram illustrating an example of a configuration of a pulse generation circuit 49.

FIG. 5 is a diagram illustrating an example of a configuration of a typical switching control IC 500.

FIG. 6 is a diagram illustrating an example of an operation of a typical switching control IC 500.

FIG. 7 is a diagram illustrating an example of an operation of a switching control IC 20.

### DETAILED DESCRIPTION

At least following matters will become apparent from the descriptions of the present description and the accompanying drawings.

=====Embodiment(s)=====

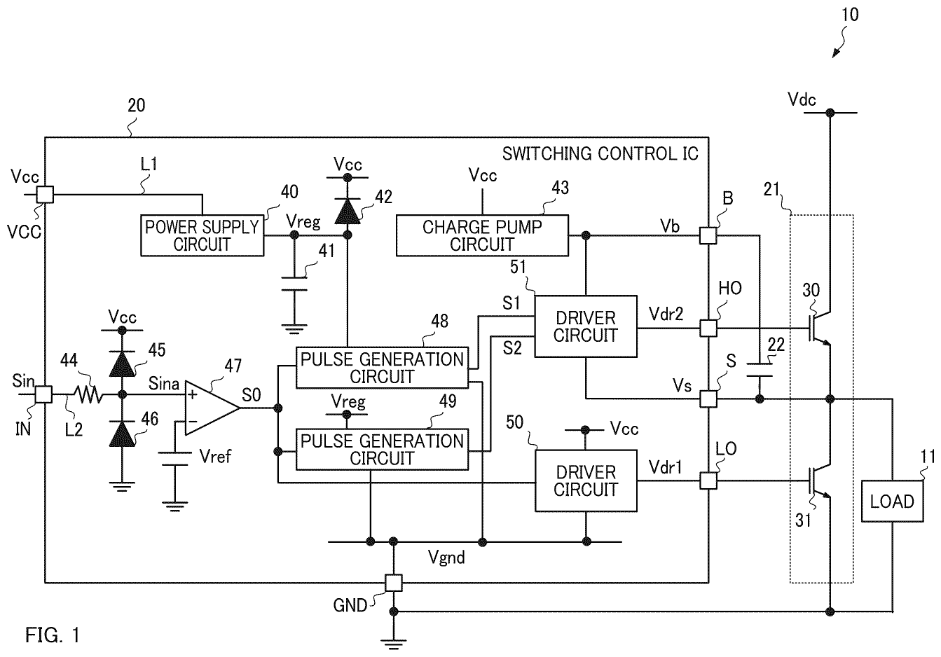

FIG. 1 is a diagram illustrating a configuration of a power module 10 which is an embodiment of the present disclosure. The power module 10 is a semiconductor device that drives a load 11 in response to an instruction from a microcomputer (not illustrated), and includes a switching control integrated circuit (IC) 20, a half-bridge circuit 21, and a capacitor 22.

The switching control IC 20 is a High Voltage Integrated Circuit (HVIC: High Voltage IC) that controls an operation of the half-bridge circuit 21 in response to an input signal Sin from the microcomputer (not illustrated). The switching control IC 20 has terminals VCC, IN, GND, B, S, HO, and LO, and details of the switching control IC 20 will be described later.

The half bridge circuit 21 is, for example, a circuit that drives a motor coil of an air conditioner of the load 11, and includes an Insulated Gate Bipolar Transistor (IGBT) 30 and an IGBT 31.

The IGBT 30 is a switching device on a high side (power supply side), and has a gate electrode connected to the terminal HO, an emitter electrode connected to the terminal S, and a collector electrode to receive a predetermined voltage Vdc (e.g., “400 V”).

The IGBT 31 is a low-side (ground-side) switching device, and has a gate electrode connected to the terminal LO, a collector electrode connected to the terminal S, and an emitter electrode that is grounded.

In an embodiment of the present disclosure, the IGBT is used as a switching device, however, for example, a metal-oxide-semiconductor (MOS) transistor or a bipolar transistor may be used. Further, the IGBT 30 corresponds to a “first switching device”, and the IGBT 31 corresponds to a “second switching device”.

The capacitor 22 has one end connected to the terminal B, and the other end connected to the terminal S. The capacitor 22 is charged by applying, to the terminal B, a bootstrap voltage Vb from a charge pump circuit 43, described later. As a result, the bootstrap voltage Vb is generated across the capacitor 22. The bootstrap voltage Vb is used to turn on the high-side IGBT 30.

For example, when a voltage Vs at the terminal S is “0 V”, the IGBT 30 is turned on in response to the voltage at the gate electrode of the IGBT 30 exceeding a threshold voltage of the IGBT 30. However, in response to the IGBT 30 being turned on, the voltage Vs at the terminal S approaches the voltage Vdc (for example, “400 V”), and thus, in order to cause the IGBT 30 to remain on, the IGBT 30 needs to be driven, with reference to the voltage Vs at the terminal S to which the emitter electrode of the IGBT 30 is connected.

In an embodiment of the present disclosure, with reference to the voltage Vs at the terminal S, a voltage higher than the voltage Vs by an amount corresponding to the bootstrap voltage Vb is generated at the terminal B. Accordingly, the switching control IC 20 can turn on the IGBT 30 by using the bootstrap voltage Vb, which will be described in detail later. Note that the power module 10 corresponds to a “semiconductor device”.

### <<<Configuration of Switching Control IC 20>>>

The switching control IC 20 includes a power supply circuit 40, a capacitor 41, diodes 42, 45, 46, the charge pump circuit 43, a resistor 44, a comparator 47, pulse generation circuits 48, 49, and driver circuits 50, 51. Note that the switching control IC 20 corresponds to a “signal processing circuit” and a “switching control circuit”.

The power supply circuit 40 generates a power supply voltage Vreg that is used inside the switching control IC 20, based on a power supply voltage Vcc (for example, “20 V”) applied to a power supply line L1 connected to the terminal VCC. As will be described in detail later, the power supply circuit 40 according to an embodiment of the present disclosure is configured to generate the stable power supply voltage Vreg even when the IGBT 31 is turned on as well. Note that the power supply voltage Vcc corresponds to a “first power supply voltage”, and the power supply voltage Vreg corresponds to a “second power supply voltage”.

### <<<Example of Power Supply Circuit 40>>>

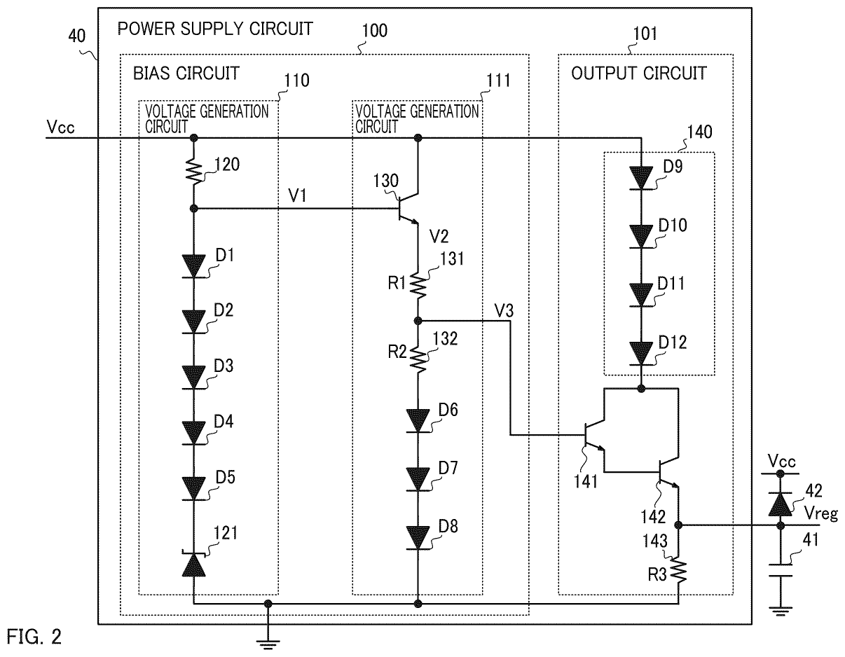

FIG. 2 is a diagram illustrating an example of a configuration of the power supply circuit 40. The power supply circuit 40 generates the temperature-compensated power supply voltage Vreg (for example, “5 V”), based on the power supply voltage Vcc. The power supply circuit 40 includes a bias circuit 100 and an output circuit 101.

The bias circuit 100 is a circuit that generates a bias voltage V3 to operate a Darlington-connected transistors (described later). The bias circuit 100 includes voltage generation circuits 110, 111.

The voltage generation circuit 110 generates a voltage V1 at a predetermined level, and includes a resistor 120, five diodes D1 to D5, a Zener diode 121.

The resistor 120, the diodes D1 to D5, and the Zener diode 121 are connected in series. Thus, in response to the power supply voltage Vcc being applied to one end of the resistor 120, the voltage V1 at the node at which the other end of the resistor 120 and the anode of the diode D1 are connected is given by Expression (1) as follows.

$$V 1 = Vz + 5 \times Vf \qquad ( 1 )$$

where “Vz” is a breakdown voltage of the Zener diode 121, and “Vf” is a forward voltage of the diodes D1 to D5.

The voltage generation circuit 111 generates the bias voltage V3, based on the voltage V1, and includes an NPN transistor 130, resistors 131, 132, and three diodes D6 to D8.

The NPN transistor 130 has a base electrode to receive the voltage V1, and an emitter electrode to which the diodes D6 to D8 are connected through the resistors 131, 132. Thus, a voltage V2 given by Expression (2) below is outputted from the emitter electrode of the NPN transistor 130.

$$V 2 = V 1 - Vbe = Vz + 5 \times Vf - Vbe \qquad ( 2 )$$

where “Vbe” is the base-emitter voltage of the NPN transistor 130. In the voltage generation circuit 111, a voltage corresponding to a difference between the forward voltage “3×Vf” of the three diodes D6 to D8 and the voltage V2 is divided by a voltage divider circuit configured with the resistors 131 and 132. Thus, the bias voltage V3 from a node at which the resistors 131 and 132 are connected is given by Expression (3) as follows.

$$\begin{matrix}V 3 = 3 \times Vf + ( V 2 - 3 \times Vf ) \times ( R 2 / ( R 1 + R 2 ) ) \\ = 3 \times Vf + ( Vz + 2 \times Vf - Vbe ) \times ( R 2 / ( R 1 + R 2 ) )\end{matrix} \qquad ( 3 )$$

where “R1” is the resistance value of the resistor 131, and “R2” is the resistance value of the resistor 132.

The output circuit 101 outputs the predetermined power supply voltage Vreg, based on the bias voltage V3, and includes a withstand voltage circuit 140, NPN transistors 141, 142, and a resistor 143.

The withstand voltage circuit 140 protects the NPN transistors 141, 142 from an overvoltage, and includes four diodes D9 to D12 connected in series.

The emitter electrode of the NPN transistor 141 is connected to the base electrode of the NPN transistor 142, and the collector electrode of the NPN transistor 141 is connected to the collector electrode of the NPN transistor 142. Accordingly, the NPN transistors 141 and 142 according to an embodiment of the present disclosure are Darlington-connected, and thus can drive a larger load.

Further, as described above, the voltage V3 is applied to the base electrode of the NPN transistor 141 in a first stage, and thus the power supply voltage Vreg given by Expression (4) below is outputted from the emitter electrode of the NPN transistor 142.

$$\begin{matrix}Vreg = V 3 - 2 \times Vbe \\ = ( 3 \times Vf + ( Vz + 2 \times Vf - Vbe ) \times ( R 2 / ( R 1 + R 2 ) ) - 2 \times Vbe\end{matrix} \qquad ( 4 )$$

The resistor 143 is an element to steadily generate the power supply voltage Vreg. Specifically, in the case where the resistor 143 is not provided, the current flowing through the NPN transistors 141 and 142 reaches zero, in response to the power supply circuit 40 becoming under no load. Thus, the generation of the power supply voltage Vreg is stopped.

Then, from this state, if the current starts flowing through the load of the power supply circuit 40, it takes time for the power supply circuit 40 to generate the power supply voltage Vreg.

In an embodiment of the present disclosure, even when the power supply circuit 40 is under no load, the current continues flowing through the resistor 143. Thus, the power supply circuit 40 can steadily generate the predetermined power supply voltage Vreg, irrespective of the state of the load of the power supply circuit 40.

Further, the temperature coefficient of the breakdown voltage “Vz” of the Zener diode 121 is positive, and the temperature coefficient of the forward voltage “Vf” of the diodes D1 to D12 is negative. Further, the temperature coefficient of the base-emitter voltage “Vbe” is negative.

Further, in an embodiment of the present disclosure, the same type of resistors (for example, polysilicon) with the same temperature coefficient are used as the resistors 131 and 132. Accordingly, the temperature coefficient of the term “R2/(R1+R2)” in Expression (4) can be substantially ignored.

In an embodiment of the present disclosure, for example, the number of the diodes D1 to D12 is adjusted based on Expression (4) such that the power supply voltage Vreg is temperature-compensated. Accordingly, the level of the power supply voltage Vreg is constant irrespective of the temperature. Further, in an embodiment of the present disclosure, it is possible to cause the power supply voltage Vreg to reach a desired level by changing the resistance ratio between the resistors 131 and 132.

As such, the power supply circuit 40 includes the Darlington-connected NPN transistors 141 and 142, and thus the output current capability is high. Further, the power supply circuit 40 can output the temperature-compensated power supply voltage Vreg at a predetermined level (for example, “5 V”).

The capacitor 41 in FIG. 1 is an element to stabilize the power supply voltage Vreg, and has one end to receive the power supply voltage Vreg and the other end that is grounded.

In response to the power supply voltage Vcc dropping below a predetermined voltage level (for example, the charge voltage of the capacitor 41), the diode 42 is turned on, to thereby discharge the capacitor 41, which will be described in detail later. The diode 42 has an anode connected to the capacitor 41, and a cathode connected to the power supply line L1. Note that the diode 42 corresponds to a “discharge circuit”, and a “second diode”.

The charge pump circuit 43 generates the bootstrap voltage Vb for charging the capacitor 22, based on the power supply voltage Vcc, for example.

The resistor 44 is an element to restrict the current flowing through the diodes 45, 46 (described later), and is provided between a signal line L2 connected to the terminal IN and the non-inverting input of the comparator 47 (described later).

The diodes 45, 46 are elements to protect the integrated circuit from static electricity inputted from the terminal IN. The diode 45 is turned on and causes the voltage level of a signal Sina to reach a voltage level that is higher than the power supply voltage Vcc by an amount corresponding to the forward voltage of the diode 45, in response to the static electricity of a positive voltage higher than the power supply voltage Vcc being inputted from the terminal IN, for example. On the other hand, the diode 46 is turned on and causes the voltage level of the signal Sina to reach a voltage level that is lower than the ground voltage by an amount corresponding to the forward voltage of the diode 46, in response to the static electricity of a negative voltage lower than the ground voltage being inputted from the terminal IN, for example.

The diode 45 has an anode connected to the non-inverting input of the comparator 47 (described later) and the resistor 44, and a cathode connected to the power supply line L1. Further, the diode 46 has an anode that is grounded and a cathode connected to the non-inverting input of the comparator 47 (described below) and the resistor 44. Note that the diode 45 corresponds to a “first diode”, and the diode 46 corresponds to a “third diode”.

The comparator 47 is a circuit that detects the level of the input signal Sin inputted through the signal line L2, and outputs a signal S0 of the same the logic level as the logic level of the input signal Sin. Specifically, in response to the input signal Sin reaching a high level (hereinafter, referred to as high or high level), the comparator 47 outputs the high signal S0, and in response to the input signal Sin reaching a low level (hereinafter, referred to as low or low level), the comparator 47 outputs the low signal S0. Further, the comparator 47 has a non-inverting input to receive the signal Sina that is based on the input signal Sin, and an inverting input to receive the reference voltage Vref. Note that the comparator 47 operates based on the power supply voltage Vreg.

The pulse generation circuit 48 outputs a pulse signal to control the switching of the IGBT 30 in response to the signal S0. Specifically, in response to the signal S0, the pulse generation circuit 48 detects the rising edge of the input signal Sin, and outputs a set pulse signal S1 to turn on the high-side IGBT 30. Note that the pulse generation circuit 48 operates based on the power supply voltage Vreg.

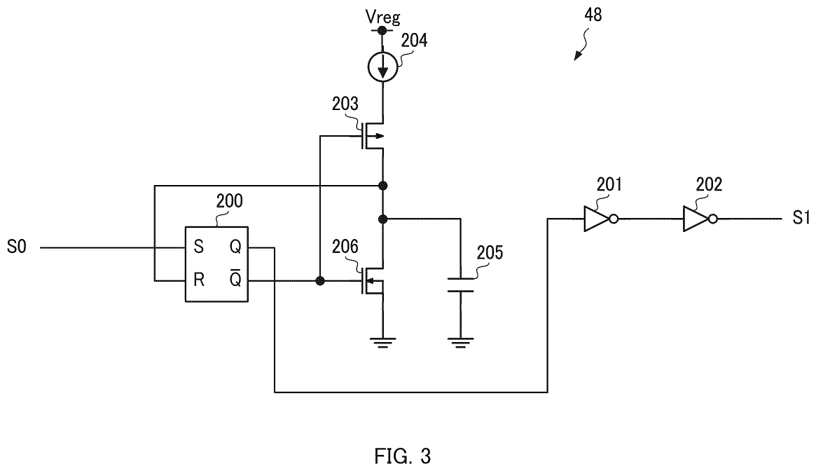

As illustrated in FIG. 3, the pulse generation circuit 48 includes an SR flip-flop 200, inverter circuits 201, 202, a P-channel metal-oxide-semiconductor (PMOS) transistor 203, a current source 204, a capacitor 205, and an N-channel metal-oxide-semiconductor (NMOS) transistor 206.

The SR flip-flop 200 is a circuit that generates the set pulse signal S1, and that causes the Q output thereof to be high in response to the set input thereof receiving the high signal S0. Then, the high set pulse signal S1 is outputted through the inverter circuits 201, 202.

In this case, the Q-bar output of the SR flip-flop 200 goes low, and thus the PMOS transistor 203 is turned on. Then, the capacitor 205 is charged with the current from the current source 204.

In response to the charge voltage of the capacitor 205 exceeding the threshold voltage of the reset input of the SR flip-flop 200, the SR flip-flop 200 causes the Q output to be low. Then, the low set pulse signal S1 is outputted through the inverter circuits 201, 202.

In this case, the Q-bar output of the SR flip-flop 200 goes high, and thus the PMOS transistor 203 is turned off. Meanwhile, the NMOS transistor 206 is turned on, and thus the capacitor 205 is discharged. As such, upon receiving the high signal S0, the pulse generation circuit 48 outputs the set pulse signal S1 with a predetermined pulse width. Note that the SR flip-flop 200, the inverter circuits 201, 202, and the current source 204 operate based on the power supply voltage Vreg. Further, the pulse generation circuit 48 corresponds to a “second detection circuit”, and the set pulse signal S1 corresponds to a “second detection result”.

The pulse generation circuit 49 outputs a pulse signal to control the switching of the IGBT 30 in response to the signal S0. Specifically, in response to the signal S0, the pulse generation circuit 49 detects the falling edge of the input signal Sin, and outputs a reset pulse signal S2 to turn off the high-side IGBT 30. Note that the pulse generation circuit 49 operates based on the power supply voltage Vreg.

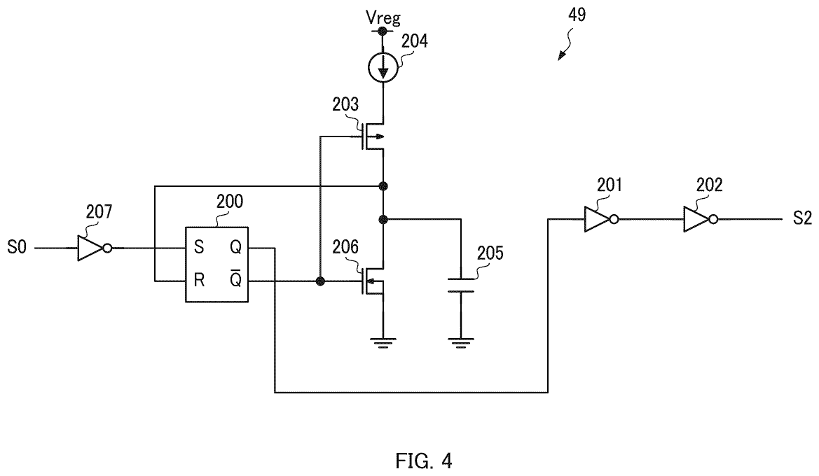

As illustrated in FIG. 4, the pulse generation circuit 49 includes the SR flip-flop 200, the inverter circuits 201, 202, 207, the PMOS transistor 203, the current source 204, the capacitor 205, and the NMOS transistor 206.

The pulse generation circuit 49 is configured similarly to the pulse generation circuit 48 except for the inverter circuit 207. Accordingly, the pulse generation circuit 49 outputs the reset pulse signal S2 with a predetermined pulse width, upon receiving the low signal S0. Note that the inverter circuit 207 operates based on the power supply voltage Vreg. Further, each of the set pulse signal S1 and the reset pulse signal S2 according to an embodiment of the present disclosure is a pulse signal whose amplitude level changes in a range from 0 V to the level of the power supply voltage Vreg (for example, 5 V). Note that the pulse generation circuit 49 corresponds to a “first detection circuit”, and the reset pulse signal S2 corresponds to a “first detection result”.

The driver circuit 50 drives the low-side IGBT 31 in response to the control signal S0. Specifically, the driver circuit 50 outputs a high drive signal Vdr1 to the gate electrode of the IGBT 31 through the terminal LO in response to the low control signal S0. As a result, the IGBT 31 is turned on. On the other hand, the driver circuit 50 outputs a low drive signal Vdr1 to the gate electrode of the IGBT 31 through the terminal LO in response to the high control signal S0. As a result, the IGBT 31 is turned off. Note that the driver circuit 50 operates based on the power supply voltage Vcc. Further, the driver circuit 50 corresponds to a “second driver circuit”.

The driver circuit 51 turns on the high-side IGBT 30 in response to the set pulse signal S1, and turns off the IGBT 30 in response to the reset pulse signal S2. Specifically, upon receiving the set pulse signal S1, the driver circuit 51 outputs a high drive signal Vdr2 to the gate electrode of the IGBT 30 through the terminal HO. On the other hand, upon receiving the reset pulse signal S2, the driver circuit 51 outputs a low drive signal Vdr2 to the gate electrode of the IGBT 30 through the terminal HO.

Here, the drive signal Vdr2 changes the logic level thereof with reference to the voltage Vs at the terminal S. Thus, the IGBT 30 is turned on in response to the high drive signal Vdr2, and is turned off in response to the low drive signal Vdr2. Note that the driver circuit 51 corresponds to a “first driver circuit”.

<<<<Configuration and Operation of Typical switching Control IC 500>>>

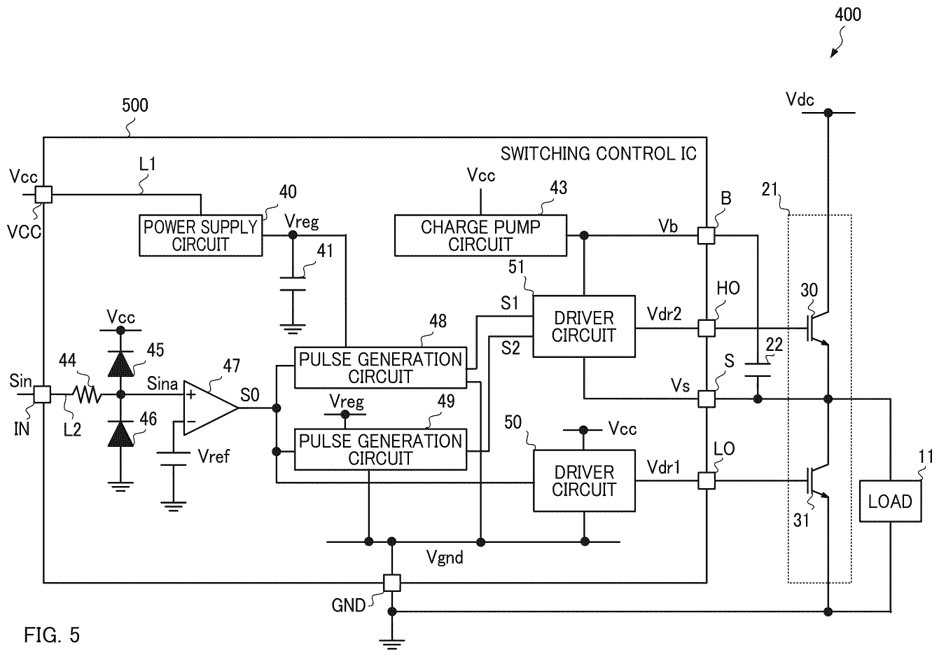

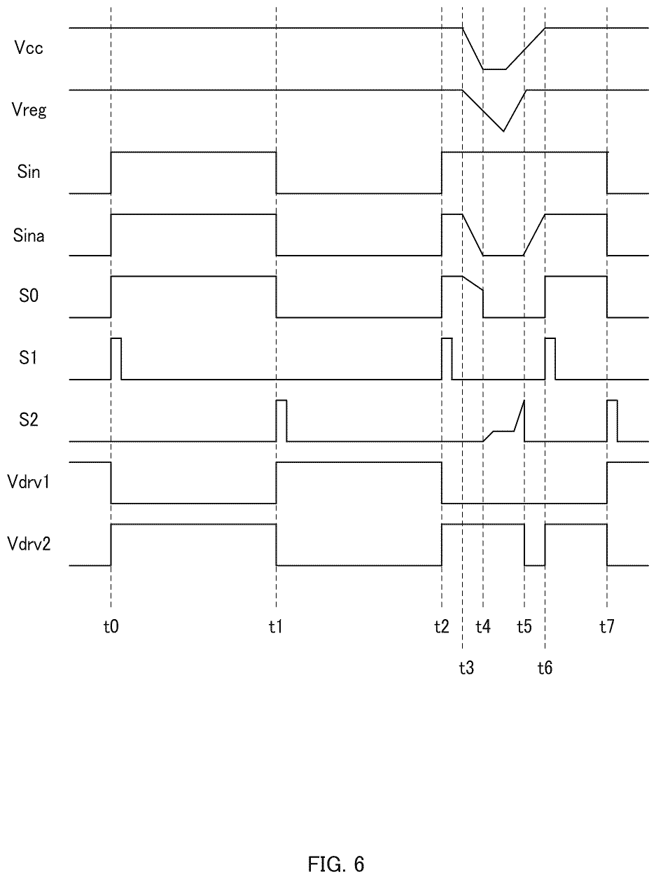

FIG. 5 is a diagram illustrating an example of a configuration of a typical switching control IC 500, and FIG. 6 is a diagram to explain an operation of the switching control IC 500. Here, as illustrated in FIG. 5, the switching control IC 500 is included in a power module 400, and is the switching control IC obtained by omitting the diode 42 from the switching control IC 20.

First, in response to the input signal Sin going high at time t0, the signal Sina goes high as well, and the comparator 47 in FIG. 5 outputs the high signal S0 as well. Further, in response to the control signal S0 going high, the pulse generation circuit 48 outputs the high set pulse signal S1. As a result, the high drive signal Vdr2 is outputted from the driver circuit 51 on the high side.

Then, the driver circuit 50 on the low-side changes the drive signal Vdr1 to low in response to the high control signal S0. As a result, the IGBT 30 is turned on and the IGBT 31 is turned off.

Further, in response to the input signal Sin going low at time t1, the signal Sina goes low as well, and the comparator 47 outputs the low signal S0 as well. In response to the control signal S0 going low, the pulse generation circuit 49 outputs the high reset pulse signal S2. As a result, the driver circuit 51 outputs the low drive signal Vdr2.

Then, the driver circuit 50 changes the drive signal Vdr1 to high in response to the low control signal S0. As a result, the IGBT 30 is turned off and the IGBT 31 is turned on.

Further, in response to the input signal Sin going high at time t2, the switching control IC 500 operates in the same manner as at time t0.

Further, in response to the power supply voltage Vcc dropping at time t3, the power supply voltage Vreg starts to drop as well. With a reduction in the power supply voltage Vcc, the voltage at the connection point between the diodes 45 and 46 in FIG. 5 is discharged towards the power supply voltage Vcc through the diode 45, and thus the signal Sina lowers. Further, with a reduction in the power supply voltage Vreg, the level of the signal S0 outputted by the comparator 47 starts to lower as well.

Further, in response to the voltage level of the power supply voltage Vcc dropping below the predetermined level (for example, dropping to 0 V) at time t4, the signal Sina becomes lower than the reference voltage Vref, and thus the comparator 47 outputs the low signal S0.

In this event, the capacitor 41 in FIG. 5 is not discharged. Thus, with the falling edge of the signal S0, the pulse generation circuit 49 attempts to output the high signal S2, because the inverter circuit 207 outputs a high signal and the SR flip-flop causes the Q output thereof to be high. However, the power supply voltage Vreg has been lower than, for example, 5V, and thus the reset pulse signal S2 is not recognized by the driver circuit 51. Thus, the driver circuit 51 continues outputting the high drive signal Vdr2.

Then, in response to the power supply voltage Vreg reaching, for example, 5 V with the power supply voltage Vcc starting to be restored at time t5, the pulse generation circuit 49 outputs the reset pulse signal S2 corresponding to the voltage level of the power supply voltage Vreg, with the power supply voltage Vreg being restored.

As a result, the driver circuit 51 recognizes the reset pulse signal S2 and outputs the low drive signal Vdr2. Accordingly, the driver circuit 51 should output the high drive signal Vdr2 since the high signal Sin is inputted, however, due to a reduction in the power supply voltage Vcc, such malfunction that the low drive signal Vdr2 is outputted occurs.

Thereafter, in response to the power supply voltage Vcc being restored at time t6, the signal Sina changes, with a change in the voltage level of the power supply voltage Vcc, to rise higher than the reference voltage Vref, and thus the comparator 47 outputs the high signal S0. Then, the pulse generation circuit 48 detects the rising edge of the signal S0 and outputs the high set pulse signal S1. Further, the driver circuit 51 outputs the high drive signal Vdr2 in response to the high set pulse signal S1.

Further, upon receiving the low signal Sin at time t7, the switching control IC 500 performs the same operation as at time t1. Hereinafter, the same or similar operation will be repeated. Note that during the time period during which the power supply voltage Vcc has been lowered, the driver circuit 50 will not turn on the IGBT 31, because the power supply voltage Vcc has dropped, even if receiving the low signal S0.

### <<<Operations of Switching Control IC 20>>>

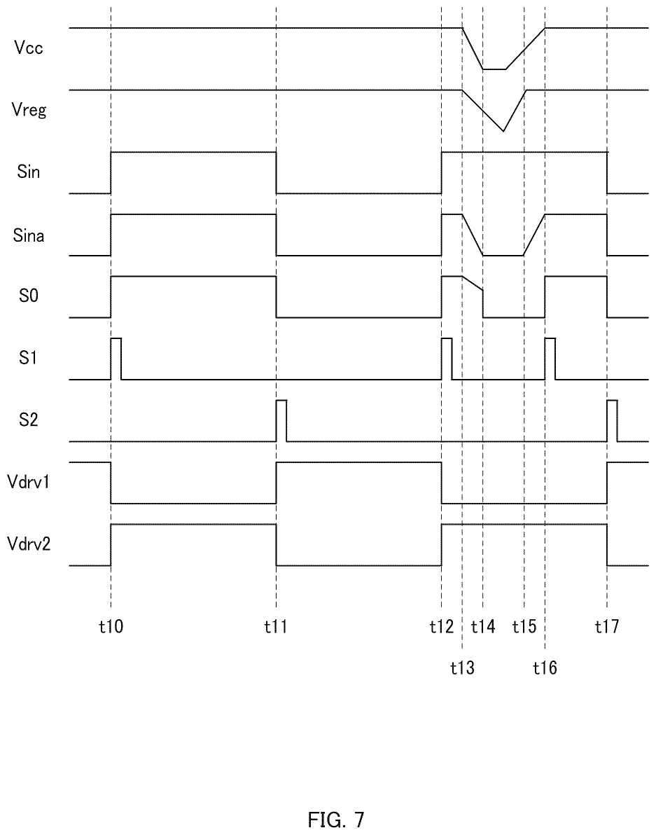

FIG. 7 is a diagram to explain an operation of the switching control IC 20. Note that operations from time t10 to t13 and t17 are the same or similar to the operations from time t0 to t3 and t7 in FIG. 6, respectively, and thus a description thereof will be omitted.

Further, in response to the level of the power supply voltage Vcc dropping below a predetermined level (for example, dropping to 0 V) at time t14, the signal Sina drops below the reference voltage Vref, as in the case at time t4 in FIG. 6, and thus the comparator 47 outputs the low signal S0.

Further, in this event, the capacitor 41 in FIG. 1 is discharged to the power supply voltage Vcc (for example, 0 V) by the diode 42, and the power supply voltage Vreg reaches, for example, 0 V, and thus, even if the signal S0 falls, the inverter circuit 202 outputs the low signal. Thus, the pulse generation circuit 49 is not able to output the high signal S2. As a result, the driver circuit 51 continues outputting the high drive signal Vdr2.

Then, with the power supply voltage Vcc starting to be restored at time t15, the inverter circuit 207 in FIG. 4 does not output the high signal, even if the power supply voltage Vreg reaches, for example, 5 V, and thus the SR flip-flop does not cause the Q output thereof to be high. Thus, with the power supply voltage Vreg being restored, the pulse generation circuit 49 does not output the reset pulse S2 corresponding to the voltage level of the power supply voltage Vreg.

Thereafter, in response to the power supply voltage Vcc being restored at time t16, the signal Sina changes with a change in the voltage level of the power supply voltage Vcc, to thereby rise above the reference voltage Vref, and thus the comparator 47 outputs the high signal S0. Then, the pulse generation circuit 48 detects the rising edge of the signal S0, to thereby output the high set pulse signal S1. On the other hand, the driver circuit 51 continues outputting the high drive signal Vdr2, even if receiving the high set pulse signal S1. Accordingly, the switching control IC 20 does not malfunction such that the low drive signal Vdr2 is outputted due to a reduction in the power supply voltage Vcc.

This makes it possible to provide a signal processing circuit capable of preventing malfunction even when the external power supply voltage drops.

### ===Summary===

The power module 10 according to an embodiment of the present disclosure has been described above. The switching control IC 20 includes the power supply circuit 40, the diode 42, the pulse generation circuit 49, and the diode 45. The diode 42 is connected to the capacitor 41 that stabilizes the power supply voltage Vreg outputted by the power supply circuit 40, and thus in response to the power supply voltage Vcc dropping to, for example, 0V, the capacitor 41 is discharged. Therefore, the pulse generation circuit 49 does not output the high reset pulse signal S2, even if the power supply voltage Vcc drops.

This makes it possible to provide a signal processing circuit capable of preventing malfunction even when the external power supply voltage drops.

Further, the switching control IC 20 includes the pulse generation circuit 48 and the driver circuit 51. This makes it possible to turn on and off the IGBT 30.

Further, the discharge circuit that discharges the capacitor 41 is the diode 42. This makes it possible to prevent malfunction of the switching control IC 20 with a simple circuit configuration.

Further, in the switching control IC 20, the diode 46 is provided, together with the diode 45, to the signal line L2. This reduces the effect of static electricity inputted through the signal line L2 on the switching control IC 20.

Further, the power module 10 includes the IGBTs 30, 31 and the switching control IC 20, and the switching control IC 20 includes the power supply circuit 40, the diodes 42, 45, the pulse generation circuits 48, 49, and the driver circuits 50, 51. The diode 42 is connected to the capacitor 41 that stabilizes the power supply voltage Vreg outputted by the power supply circuit 40, and thus in response to the power supply voltage Vcc dropping to, for example, 0V, the capacitor 41 is discharged. Therefore, the pulse generation circuit 49 does not output the high reset pulse signal S2, even if the power supply voltage Vcc drops. As a result, even if the power supply voltage Vcc drops, the IGBT 30 is not erroneously turned off.

The present disclosure is directed to provision of a signal processing circuit capable of preventing malfunction even when an external power supply voltage drops.

According to the present disclosure, it is possible to provide a signal processing circuit capable of preventing malfunction even when an external power supply voltage drops.

An embodiment of the present disclosure described above is simply to facilitate understanding of the present disclosure and is not in any way to be construed as limiting the present disclosure. Further, the present disclosure may variously be changed or altered without departing from its essential features and encompass equivalents thereof.

What is claimed is:

1. A signal processing circuit comprising:
a power supply line configured to receive a first power supply voltage;
a signal line configured to receive an input signal;
a power supply circuit configured to receive the first power supply voltage from the power supply line;
a capacitor connected to the power supply circuit, the power supply circuit generating a second power supply voltage at the capacitor based on the received first power supply voltage;
a discharge circuit configured to discharge the capacitor, in response to the first power supply voltage dropping below a predetermined voltage level;
a first detection circuit configured to operate based on the second power supply voltage, and detect a falling edge of the input signal inputted through the signal line; and
a first diode having an anode thereof connected to the signal line and a cathode thereof connected to the power supply line.

2. The signal processing circuit according to claim 1, further comprising:
a second detection circuit configured to operate based on the second power supply voltage, and detect a rising edge of the input signal inputted through the signal line; and
a driver circuit configured to drive a switching device in response to a first detection result of the first detection circuit and a second detection result of the second detection circuit.

3. The signal processing circuit according to claim 1, wherein the discharge circuit includes a second diode having an anode thereof connected to the capacitor and a cathode thereof connected to the power supply line.

4. The signal processing circuit according to claim 3, further comprising a third diode having a cathode thereof connected to the signal line and an anode thereof that is grounded.

5. A semiconductor device comprising:
a first switching device on a power supply side;
a second switching device on a ground side, the first switching device and the second switching device being configured to drive a load; and
a switching control circuit configured to control switching of the first switching device and the second switching device, the switching control circuit including:
a power supply line configured to receive a first power supply voltage,
a signal line configured to receive an input signal,
a power supply circuit configured to receive the first power supply voltage from the power supply line,
a capacitor connected to the power supply circuit, the power supply circuit generating a second power supply voltage at the capacitor based on the received first power supply voltage,
a discharge circuit configured to discharge the capacitor, in response to the first power supply voltage dropping below a predetermined voltage level,
a first detection circuit configured to operate based on the second power supply voltage, and detect a falling edge of the input signal inputted through the signal line,
a second detection circuit configured to operate based on the second power supply voltage, and detect a rising edge of the input signal inputted through the signal line,
a first driver circuit configured to drive the first switching device, in response to a first detection result of the first detection circuit and a second detection result of the second detection circuit,
a second driver circuit configured to drive the second switching device in response to the input signal, and
a first diode having an anode thereof connected to the signal line and a cathode thereof connected to the power supply line.
